(19) United States
(12) Patent Application Publication
(10) Pub. No.: US 2006/0226849 A1
(43) Pub. Date: Oct. 12, 2006

(54) Method and device for detecting a current

(76) Inventors: Cho-Hsine Liao, Taipei Hsien (TW); Ju-Yi Hung, Taipei Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/102,692

(22) Filed: Apr. 11, 2005

(51) Int. Cl. G01R 31/08

(52) U.S. Cl. 324/522

(57) ABSTRACT

A method and device for detecting a current are described. The present invention displays a value and looks for loads current of the CPU through an LED, a 7-segment display or a display monitor.

### BACKGROUND OF THE INVENTION

1. Field of the Invention

The present invention is related to a method and device for detecting a current, and especially a method of using the current detecting device to detecting current loading of a CPU.

2. Description of Related Art

A BIOS of motherboard has set CPU voltage functions. The motherboard can set the voltage value and the voltage indication mark (VID) of the corresponding relation that produce the new voltage indication mark signal, and convert the new voltage to a basic voltage via a digital/analog converter, then delivers the basic voltage to the CPU. Finally, the voltage is output and the voltage value is set after an adjustment circuit. When different voltages of the CPU are used, the motherboard can act according to the CPU voltage to output the most suitable voltage.

The prior art can only detect the VID value of the CPU but cannot display the real current value. The different frequency speed CPU generates different currents when executing a program. However, the prior art is unable to display the current value.

### SUMMARY OF THE INVENTION

The object of the present invention resolves the display disadvantage of the CPU voltage value in the prior art. The present invention displays a current value via a display unit and looks for current loading of the CPU.

The method of the present invention transmits a current detect signal generated by a CPU, gives a current value of the current detect signal, converts the current value to a voltage value, determines whether the current value exceeds a predetermined value in a comparison operation unit, and outputs a voltage dissimilitude value on a display unit.

The device for detecting a current comprises a CPU to generate a current signal, a detection unit coupled to said CPU to detect the current signal generated by the CPU, a conversion unit coupled to said detection unit to convert the current signal to a voltage value, a comparison operation unit coupled to said conversion unit to compare a converted voltage value with a predetermined value of the comparison operation unit, and a display unit coupled to the comparison operation unit to display a voltage dissimilitude value after comparison.

To provide a further understanding of the invention, the following detailed description illustrates embodiments and examples of the invention, this detailed description being provided only for an illustration of the invention.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 shows a schematic diagram of a device for detecting current according to the first embodiment of the present invention;

FIG. 2 shows a schematic diagram of a device for detecting current according to the second embodiment of the present invention;

FIG. 3 shows a schematic diagram of a device for detecting current according to the third embodiment of the present invention;

FIG. 4 shows a flow chart of a method for detecting current according to the first embodiment of the present invention;

FIG. 5 shows a flow chart of a method for detecting current according to the second embodiment of the present invention; and

FIG. 6 shows a flow chart of a method for detecting current according to the third embodiment of the present invention.

### DETAILED DESCRIPTION OF PREFERRED EMBODIMENTS

The prior art only detects the VID value of the CPU and doesn't display a real current value. The present invention displays a current value and looks for current loading of the CPU via a display unit.

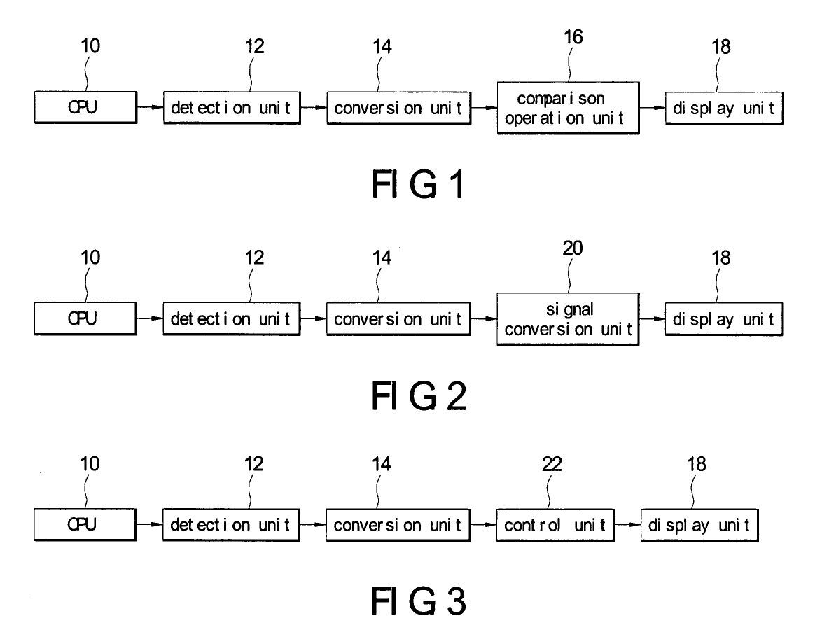

FIG. 1 shows a schematic diagram of a device for detecting current according to the first embodiment of the present invention. A CPU 10 generates a current signal. A detection unit 12 is coupled to the CPU 10 to detect the current signal generated by the CPU 10. A conversion unit 14 is coupled to the detection unit 12 to convert the current signal to a voltage value. A comparison operation unit 16 is coupled to the conversion unit 14 to compare the voltage value after conversion with a predetermined value of the comparison operation unit 16. The comparison operation unit is a 4-BIT magnitude comparator. A display unit 18 coupled to the comparison operation unit 16 displays a voltage dissimilitude value after comparison. The display unit is at least one LED.

FIG. 2 shows a schematic diagram of a device for detecting current according to the second embodiment of the present invention. A CPU 10 generates a current signal. A detection unit 12 coupled to said CPU 10 detects the current signal generated by the CPU 10. A conversion unit 14 coupled to said detection unit 12 converts the current signal to a voltage value. A signal conversion unit 20 coupled to the conversion unit 14 converts the voltage value to a digital signal from an analog signal. The signal conversion unit is an A/D converter. A display unit 18 is coupled to the signal conversion unit 20 to output the digital signal. The display unit is an LCD monitor or a CRT monitor.

FIG. 3 shows a schematic diagram of a device for detecting current according to the third embodiment of the present invention. A CPU 10 generates a current signal. A detection unit 12 coupled to CPU 10 detects the current signal generated by the CPU 10. A conversion unit 14 coupled to the detection unit 12 converts the current signal to a voltage value. A control unit 22 is coupled to the conversion unit. The control unit includes software, and reads the voltage value using the software. A display unit 18 coupled to said control unit displays the voltage value. The display unit is an LCD monitor or a CRT monitor.

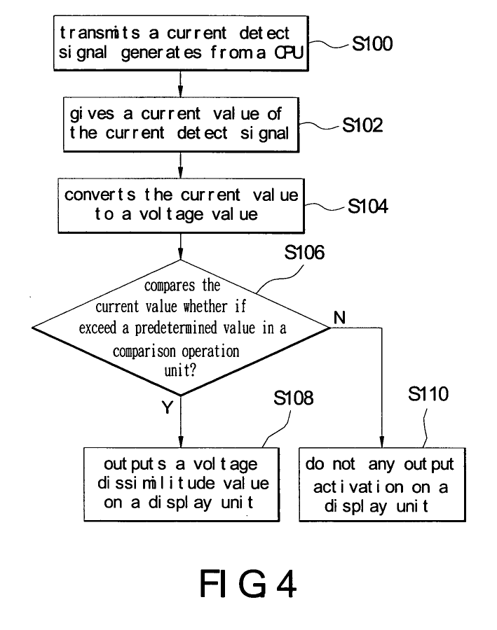

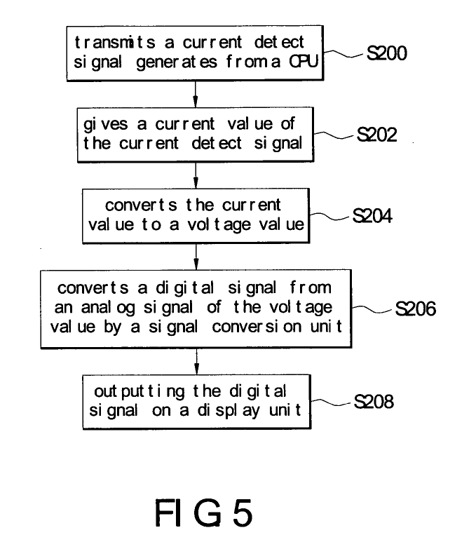

FIG. 4 shows a flow chart of a method for detecting current according to the first embodiment of the present invention. The steps include transmitting a current detect signal, generated by a CPU S100. A current value is provided by the current detect signal S102. The current value is given for detection and created by a detection unit. The current value is converted into a voltage value S104 and whether the current value exceeds a predetermined value is determined in a comparison operation unit S106. The comparison operation unit is a 4-Bit magnitude comparator. If the result of the step of comparing the current value is yes, then a voltage dissimilitude value is displayed on a display unit S108. If the comparison results in no, there is not any output activation on a display unit S110. The display unit is at least one LED.

As mentioned above, the method of the first embodiment matches the device of the first embodiment. The first embodiment dynamically detects CPU current loading, and converts voltage value via the conversion unit. Finally, the voltage value is compared with the 4-Bit magnitude comparator. When voltage value over each section of design predetermines the voltage value, the complexes of LED are turned on. When the voltage value exceeds the first section, the first LED is turned on and so on. The complexes of LED are increasingly turned on when the current loading is overloaded. Otherwise, the complexes of LED are turned off. The complexes of LED are streamlined when the current loading dissimilitude is very large. A user can see the current loading of the CPU clearly.

FIG. 5 shows a flow chart of a method for detecting current according to the second embodiment of the present invention. The steps include transmitting a current detect signal generated from a CPU (S200). A current value is provided by the current detect signal (S202) and the current value is converted into a voltage value (S204). The current value is given for detection and is created by a detection unit. A digital signal is converted from an analog signal of the voltage value by a signal conversion unit S206. The signal conversion unit is an A/D converter. The digital signal is displayed on a display unit S208. The display unit is a 7-segment display.

As mentioned above, the method of the second embodiment matches the device of the second embodiment. The second embodiment is different from the first embodiment in that the voltage value is provided via a comparator rather than via the A/D converter and the display unit is changed to 7-segment displays. The analog voltage value converts the digital voltage value. The digital value is output on the 7-segment display and shows the current loading. The 7-segment display shows the current value when the current loading dissimilitude is very large. A user can see the current loading of the CPU clearly.

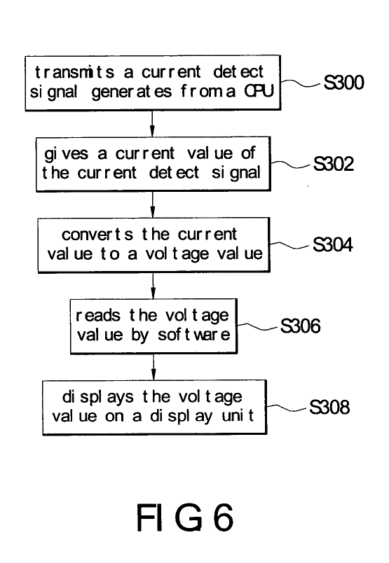

FIG. 6 shows a flow chart of a method for detecting current according to the third embodiment of the present invention. The steps include transmitting a current detect signal, which is generated by a CPU S300. A current value is provided by the current detect signal S302 and the current value is converted into a voltage value S304. The current value is provided for detection and is created by a detection unit. The voltage value is read by software and displayed on a display unit. The display unit is an LCD monitor or a CRT monitor.

As mentioned above, the method of the third embodiment matches the device of the third embodiment. The third embodiment is different from the first embodiment in that the control unit replaces the LED and uses software thereinside for the control unit to read the voltage value. The voltage value is displayed on an LCD monitor or a CRT monitor. The LCD monitor or CRT monitor shows the voltage value when the current loading dissimilitude is very large. A user can clearly see the current loading of the CPU.

The current of each CPU loads different current values in for power-on, entry operation system platform or playing 3D games. The present invention shows the current value via the LED, the 7-segment display or the display monitor. A user can see the current loading of the CPU clearly.

Those skilled in the art will readily appreciate that the above description is only illustrative of specific embodiments and examples of the invention. The invention should therefore cover various modifications and variations made to the herein-described structure and operations of the invention, provided they fall within the scope of the invention as defined in the following appended claims.

1. A method for detecting a current comprising:
transmitting a current detect signal generated by a CPU;
detecting said current detect signal and creating a current value of said current detect signal by a detection unit;
converting said current value of said current detect signal to a voltage value in a conversion unit;
comparing the voltage value with a predetermined voltage value in a comparison operation unit to determine whether the voltage value exceeds said a predetermined voltage value;
determining a voltage dissimilitude value between said voltage value and said predetermined voltage value; and
outputting the voltage dissimilitude value on a display unit.

2. (canceled)

3. The method in claim 1, wherein the comparison operation unit is a 4-Bit magnitude comparator.

4. The method in claim 1, wherein an output signal of said comparison operation unit is coupled to said display unit only if said voltage value exceeds said predetermined voltage value.

5. The method in claim 1, wherein the display unit is at least one LED.

6-12. (canceled)

13. A device for detecting a current, comprising:
a CPU to generate a current signal;
a detection unit coupled to said CPU to detect the current signal generated by the CPU;
a conversion unit coupled to said detection unit to convert the current signal to a voltage value;
a comparison operation unit coupled to said conversion unit for comparison of said voltage value with a predetermined voltage value; and
a display unit coupled to the comparison operation unit for displaying a voltage dissimilitude value after comparison, the voltage dissimilitude value being determined as a difference between said voltage value and said predetermined voltage value.

14. The device in claim 13, wherein the comparison operation unit is a 4-BIT magnitude comparator.

15. The device in claim 13, wherein the display unit is at least one LED.

16-20. (canceled)
